(19) United States
(12) Patent Application Publication
(10) Pub. No.: US 2013/0161798 A1
(43) Pub. Date: Jun. 27, 2013

(54) GRADED DENSITY LAYER FOR FORMATION OF INTERCONNECT STRUCTURES

(71) Applicant: Hideyuki Tomizawa, Rensselaer, NY (US)

(72) Inventor: Hideyuki Tomizawa, Rensselaer, NY (US)

(73) Assignee: TOSHIBA AMERICA ELECTRONIC COMPONENTS, INC., Irvine, CA (US)

(21) Appl. No.: 13/334,257

(22) Filed: Dec. 22, 2011

(51) Int. Cl. H01L 21/311; H01L 21/31; H01L 29/02

(52) U.S. Cl. 257/635; 438/700; 438/761; 257/E21.257; 257/E21.24; 257/E29.001

(57) ABSTRACT

Methods and structure are provided for utilizing a dielectric mask layer having a gradated density structure. The density of the dielectric mask layer is greatest at the interface of the dielectric mask layer and an underlying dielectric layer. The density of the dielectric mask layer is lowest at the interface of the dielectric mask layer and an overlaying hard mask. The lower density dielectric mask layer is more susceptible to removal than the higher density dielectric mask layer. The lower density dielectric mask layer is removed during at least one of an RIE etch or a post-RIE etch wet clean. Selective removal of the lower density dielectric mask layer creates a dielectric mask layer having a rounded profile. The dielectric mask layer comprises tetraethyl orthosilicate.

### FIELD

Embodiments described herein relate generally to methods and systems for utilizing a graded density layer facilitating preferential etching for forming interconnect structures having a high integrity.

### BACKGROUND

Silicon large-scale integrated circuits, among other device technologies, are increasing in use in order to provide support for the advanced information society of the future. An integrated circuit can be composed of a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc., of resultant integrated circuits. However, as semiconductor devices and device features have become smaller, conventional fabrication techniques have become limited in their ability to produce finely defined features.

Patterning of semiconductors and integrated circuits can involve patterning several thousand openings (e.g., trenches, holes, etc.) which are subsequently filled with a conductor, such as aluminum or copper, to form conductive lines (e.g., metal lines, bus lines, bit lines, word lines, logic interconnect lines, vias, and the like), separated by interwiring spacings, and serve to interconnect active and/or passive elements of an integrated circuit. Filling with conductive material can be performed, for example, by a single damascene process or a dual damascene process.

However, as device patterning dimensions are reduced, the amount of material (e.g., interwiring spacings) available between adjacent conductive lines (e.g., interconnects, vias, trenches, holes, etc.), has further become reduced. Hence, to prevent such issues as leakage, short circuiting, crosstalk, parasitic capacitance, high resistance, and other deleterious effects, the aspect ratio of the trenches (as formed in a semiconductor assembly to be subsequently filled with a conductor, etc.) has become high (e.g., the depth of the trench is greater than the width of the trench). However, such high aspect ratio constructions can suffer from inability to seamlessly fill the trench, etc., and accordingly, the ability to fill a trench with a high integrity of conducting material is not always achievable, especially with a degree of consistency required in semiconductor manufacturing processes.

### SUMMARY

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of this summary is to present some concepts related to some exemplary non-limiting embodiments in a simplified form as a prelude to the more detailed description of the various embodiments that follow.

A multilayer semiconductor stack is formed comprising at least a dielectric layer, a hard mask layer (e.g., a metal hard mask layer), and a dielectric mask layer (e.g., a dielectric hard mask layer), wherein the dielectric mask layer separates the dielectric layer and the hard mask layer. In an embodiment, the dielectric mask is formed having a gradation in density across the thickness of the dielectric mask layer. The density of the dielectric mask layer is highest at the interface of the dielectric mask layer and the dielectric layer, and the density of the dielectric mask is lowest at the interface of the dielectric mask layer and the hard mask layer. The difference in density across the dielectric mask renders the lower density regions of the dielectric mask layer to be more susceptible to removal than a higher density region of the dielectric mask layer. Hence, the lower density dielectric mask exhibits preferential removal (e.g., by etching or as part of a wet clean operation) over the higher density dielectric mask. In an embodiment, the lower density region can be about 50% of the higher density region of the dielectric mask layer. In an embodiment, the gradated density dielectric mask layer comprises tetraethyl orthosilicate (TEOS).

In an embodiment, a first portion of the low density dielectric mask layer can be removed during a reactive ion etch (RIE) process performed to create a trench in the multilayer semiconductor stack. The first portion of the low density dielectric mask layer is removed laterally from beneath the interface with the hard mask layer. In effect, the hard mask layer is acting as an etch stop owing to the hard mask not being removed by the RIE.

In a further embodiment, a second portion of the low density dielectric mask layer can be removed during a wet clean process performed subsequent to the RIE process. The second portion of the low density dielectric mask layer is removed laterally from beneath the interface with the hard mask layer and extends the amount of low density dielectric mask layer removed. In an embodiment, the volume of the second portion of the low density dielectric mask layer is greater than the volume of the first portion of the low density dielectric mask layer. In an embodiment, the solution for wet cleaning is hydrofluoric acid (HF).

In a further embodiment, the hard mask layer is removed thereby exposing a surface of dielectric mask layer at the interface of the hard mask layer and the dielectric mask layer. Owing to the removal of the first and second portions of the dielectric mask layer, the exposed surface of the exposed dielectric mask layer has a rounded profile. In an embodiment, the hard mask layer is removed utilizing a hydrogen peroxide solution. In an embodiment, the dielectric mask layer is initially wet cleaned with HF solution and is subsequently exposed to a solution comprising hydrogen peroxide. In an embodiment, the flow of HF solution transitions to a flow of hydrogen peroxide solution, whereby the transitioning of flow of HF solution to hydrogen peroxide solution occurs in a sequential manner whereby a solution may be HF rich and then becomes hydrogen peroxide rich.

In an embodiment, the RIE process is an anisotropic etching process, while the wet clean process is an isotropic etching process. Further, the volume of dielectric mask layer being removed is a function in part of at least any of the following: density of the dielectric mask layer and respective portion being susceptible to removal, etching conditions, wet clean conditions, etc.

These, and other embodiments, are described in more detail below.

### BRIEF DESCRIPTION OF THE DRAWINGS

FIG. 1 is a block diagram depicting formation of a high-aspect ratio trench.

FIG. 2 is a block diagram depicting deposition of metal to fill the high-aspect ratio trench.

FIG. 3 is a block diagram depicting formation of voids in interconnect lines.

FIG. 4 is a block diagram depicting trench profile for formation of seamlessly filled interconnect lines.

FIG. 5 is a block diagram illustrating issues associated with formation of an interconnect line in a high-aspect ratio trench.

FIG. 6 is a block diagram illustrating a non-limiting, exemplary embodiment utilizing density gradient material and RIE in the formation of an interconnect in a high-aspect ratio trench.

FIG. 7 is a block diagram illustrating a non-limiting, exemplary embodiment utilizing density gradient material and wet cleaning in the formation of an interconnect in a high-aspect ratio trench.

FIG. 8 is a block diagram illustrating a non-limiting, exemplary embodiment utilizing density gradient material and profile rounding of interwiring structures in the formation of an interconnect in a high-aspect ratio trench.

FIG. 9 is a block diagram illustrating a non-limiting, exemplary embodiment of a barrier layer being formed on an interwiring structure.

FIG. 10 is a block diagram illustrating a non-limiting, exemplary embodiment of formation of an interconnect.

FIG. 11 is a block diagram illustrating a non-limiting, exemplary embodiment of formation of an interconnect.

FIG. 12 is a block diagram of an exemplary semiconductor stack according to an embodiment of the subject innovation.

FIG. 13 is a block diagram of an exemplary semiconductor stack according to an embodiment of the subject innovation.

### DETAILED DESCRIPTION

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The various embodiments presented herein generally relate to systems and methods for utilizing a layer formed with a gradient of material density across its thickness facilitating preferential removal of layer material to facilitate formation of interconnect structures having a high integrity. Advantage is taken of a lower density material being preferentially removed (e.g., by etching/cleaning) over a higher density counterpart.

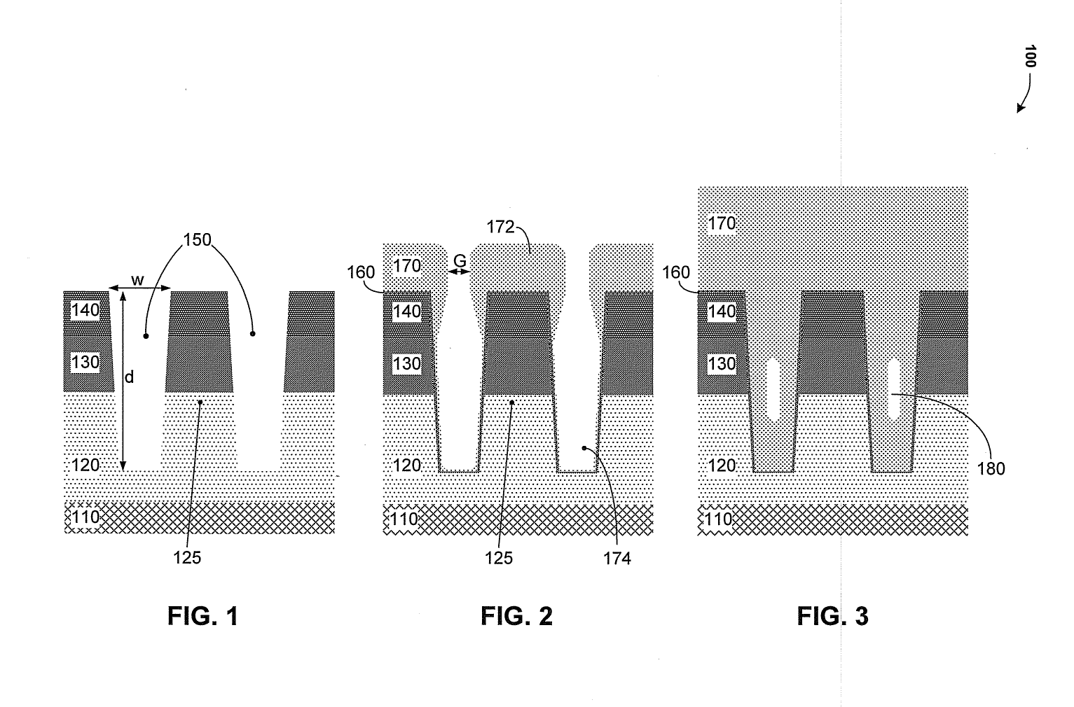

FIGS. 1-3 present issues regarding seamless filling of trenches, holes, vias, interconnects, etc., having a high aspect ratio. For readability, trenches, holes, vias, interconnects, etc., which can be formed by various means in a multilayer semiconductor stack are hereinafter referred to as a ‘trench’(es). However, it is to be appreciated that the term ‘trench’ relates to any structure resulting from removal of material comprising in multilayer semiconductor stack for which the various embodiments, presented herein, are applicable.

FIG. 1 illustrates a pair of trenches 150 formed in a layered structure comprising a base layer 110, dielectric 120, a first mask (e.g.; dielectric hard mask) layer 130, and a second mask (e.g., metal hard mask for lithography patterning) layer 140. Base layer 110 can include any suitable semiconductor material, for example, a monocrystalline silicon substrate, tri-layer cap, or the like. It is to be appreciated that base layer 110 may also comprise of a pre-existing semiconductor apparatus or multilayer stack, for example, base layer 110 may be a semiconductor device comprising a multilayer substrate comprising a plurality of layers including monocrystalline silicon, dielectric(s), insulator(s), conductor(s), interlayer dielectric(s) (ILDs), low k polymer layer, patterning film, organic film, carbon film, etc., onto which is further formed a plurality of layers as required to facilitate formation of the graded density layer, as presented herein.

In an embodiment, base layer 110 can be a diffusion barrier layer utilized to reduce such deleterious effects as parasitic capacitance. The diffusion barrier layer can comprise of any suitable dielectric such as SiN, SiCN, SiC, etc. In a further embodiment rather than base layer 110 comprising a single layer of material (e.g., a layer of SiN), base layer 110 can be formed from a plurality of layers comprising any combination of SiN, SiCN, SiC (e.g., SiN, SiCN, SiN/SiC, SiCN/SiC/SiCN, etc.). Such diffusion layer can be formed from a plurality of deposition sequences, and hence can be referred to as a tri-layer cap. The sequence of deposition can be of any order. For example, in an embodiment, SiN can be deposited first owing to the density of SiN being greater than SiC and facilitates a greater degree of prevention to the diffusion of Cu, Al, etc. Such application of a diffusion barrier layer may be where a plurality of layered structures comprising respective conductive line(s) where each layered structure is formed on an underlying structure and the diffusion barrier layer is deposited to prevent conductor comprising the conductive line(s) in an underlying structure from diffusing through to a substrate/dielectric layer formed thereover. The diffusion barrier layer(s) can be formed by any suitable technique, such as chemical vapor deposition (CVD).

Layer 120 can comprise of any material having a low dielectric constant (low-k) which is utilized to separate the various interconnects, transistors, etc., which are formed in the layered structure. As miniaturization of integrated circuits has been pursued in light of Moore's law, traditionally layer 120 may have been comprised of silicon dioxide (SiO₂), however, owing to the thinned volume of insulating dielectrics (e.g., interwiring structure 125), materials having a lower dielectric constant than SiO₂ (low-k materials such as fluorosilicate glass, carbon-doped-SiO₂, porous SiO₂, SiLK™ (from Dow Chemical), hydrogen silsesquioxane (HSQ), methylsilsesquioxane (MSQ), and also ultra low-k materials such as ultra low-k spin on glass (ultra low-k SOG)) can be utilized to form layer 120.

Layer 130 is formed on layer 120, and in an aspect can act to separate the dielectric layer 120 from mask layer 140. In an embodiment, layer 130 can comprise tetraethyl orthosilicate (TEOS), which can act a precursor to the formation of SiO₂. It is to be appreciated that while various embodiments presented herein present layer 130 comprising TEOS the various embodiments are equally directed towards any material(s) for which the various embodiments may be applicable. For example, the concept of a layer deposited having a gradation in material density (as explained further below) which enables a portion of the layer to be removed preferentially with regard to a different portion of the same layer can be applied to any suitable material and is not limited to application of structures comprising TEOS. The various embodiments presented herein can be directed to any SiO₂-like material.

Layer 140 can comprise a masking material which is utilized in the formation of the trench 150. Any suitable masking material can be utilized in layer 140, such as a titanium nitride (TiN) hard mask. Based upon the patterning of the mask layer 140, trenches (e.g., trenches 150), etc., are formed in the layered structure by any suitable technique, e.g., RIE etch. (MASKS)

FIG. 2 illustrates a layered structure (as previously described with reference to FIG. 1) being further processed with barrier layer 160 formed over the layered structure, wherein the barrier layer 160 can be utilized to minimize diffusion of conductor (e.g., metals Cu or Al) into the dielectric layer 120 during formation of the interconnects, etc., in the trenches. Further, as shown in FIG. 2, the initial deposition of a conducting layer 170 (e.g., a metalized layer comprising a conductor such as Cu, Al, and the like) is represented. However, rather than a seamless fill of material occurring, owing to the high aspect ratio of trench width (FIG. 1, ‘w’) versus trench depth (FIG. 1, ‘d’) insufficient conductor is being deposited into the bottom 174 of the trench 150. Rather, a crenellated structure can be formed whereby conductor is deposited in a deleterious manner, as shown by the non-uniform build up of metal 172 on the central interwiring structure 125. Such build up of metal 172, leads to a constriction G (compared with initial width w, FIG. 1).

As shown in FIG. 3, constriction G can prevent sufficient conductor being able to be deposited in the bottom 174 of trench(es) 150. Accordingly, as previously mentioned, trench 150 is not seamlessly filled, and rather includes void(s) 180, where void 180 can result from insufficient deposition of material (e.g., metal 172) in trenches 150, as well as shrinkage effects, insufficient ingress of material, and other defects resulting from physical constraints encountered during deposition, thereby minimizing the ability to seamlessly fill trenches 150. Hence, no matter the amount of material 170 deposited onto the layered structure, voids 180 cannot be overcome and the unwanted effects of partially filled trenches (and resulting low integrity interconnect structures, etc.) results.

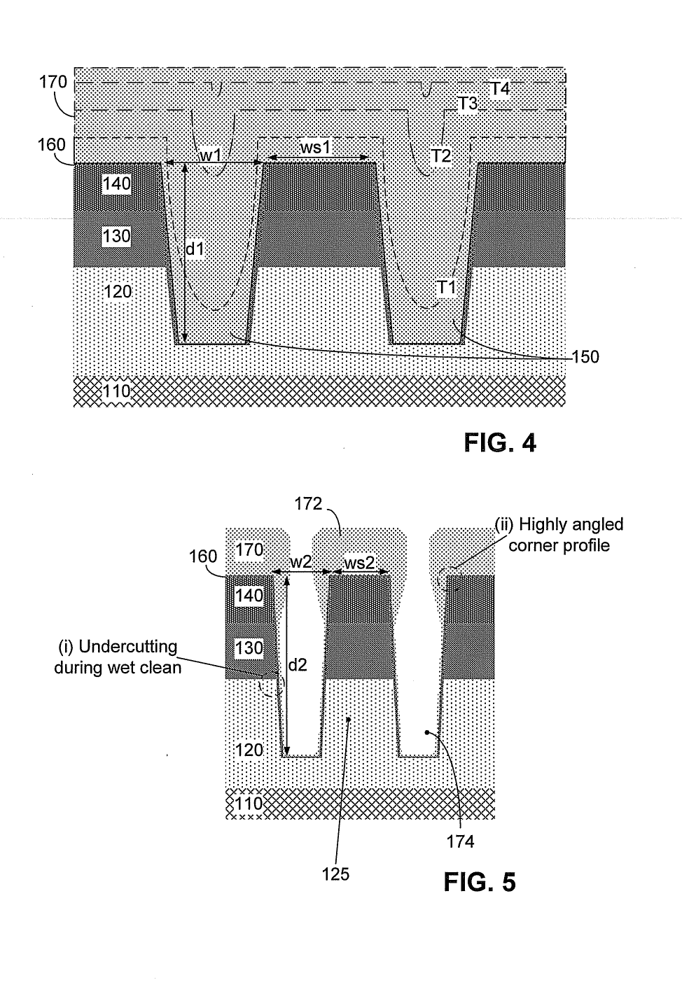

FIGS. 4 and 5 are presented to clarify the concept of aspect ratio of a trench on the ability to seamless fill the trench and corresponding interconnect formation. As shown in FIG. 4, width w1 of the trench is of a value, with reference to trench depth d1, such that the aspect ratio (w1:d1) is of a magnitude that seamless filling of trenches 150 can occur. FIG. 4 is a diagrammatic representation of trenches 150 being filled with conductor 170, where T1, T2, T3, and T4 represent chronologically sequential deposition of conductor 170. Initially, at T1, conductor 170 is deposited with initially a large volume still be filled in trench 150. However, as mentioned, owing to the favorable aspect ratio (w1:d1) no constriction of deposition occurs and trenches 150 are seamlessly filled, as shown in the T1-T2-T3-T4 progression.

In contrast, FIG. 5 (similar to FIG. 2) illustrates build up of conductor being deposited on the interwiring structures (e.g., metal 172 on ws2). Such a situation can arise owing to the aspect ratio (w2:d2) being of such magnitude to render seamless metal deposition difficult, as well as giving rise to other deleterious effects as previously mentioned.

Further, another effect depicted in FIG. 5 is (i) the undercutting at layer interfaces as experienced, for example, during a post-etch wet cleaning operation. As mentioned above, layer 120 can comprise of a dielectric (e.g., low-k, ultra low-k, etc.) and layer 130 can comprise of TEOS. Such an undercutting effect can occur during formation of the hole by RIE, where RIE can damage the dielectric layer 120. Such damage can result in discontinuity in the subsequent formation of barrier layer 160 which can result in unwanted effects during filling with conductor 170. For example, a discontinuous layer 160 may be unable to prevent diffusion of metal ions from conductive fill 170 into layer 120 and also layer 130. Diffusion of unwanted metals ions into layer 120 can give rise to previously mentioned deleterious effects such as parasitic capacitance, electrical path shorting, etc.

Further, as shown in FIG. 5, an approach to facilitate improved filling of trench 150 is (ii) to reduce the angularity of the corner profiles for the interwiring structures. Such an approach can reduce the likelihood of the formation of conductor 172 stacking on the interwiring structures 125. Hence, reduction of the aspect ratio of trenches 150 may be directed towards removal of layer 140 thereby reducing height d2 by the width of layer 140. In another aspect, improvement in filling trenches 150 may be a reduction in the angularity of the top surfaces (e.g., the corners) of interwiring structures 125. However, such approaches may involve a plurality of production operations.

The various embodiments presented herein address issues of filling high aspect ratio trenches while utilizing, in a beneficial manner, undercutting effects encountered during trench formation. Wherein, the undercutting effects can be utilized to reduce the angularity of corner profiles to effectively open up a trench to improve the ability to seamlessly fill a trench with material, and accordingly, increase the ability to form substantially sound interconnect structures.

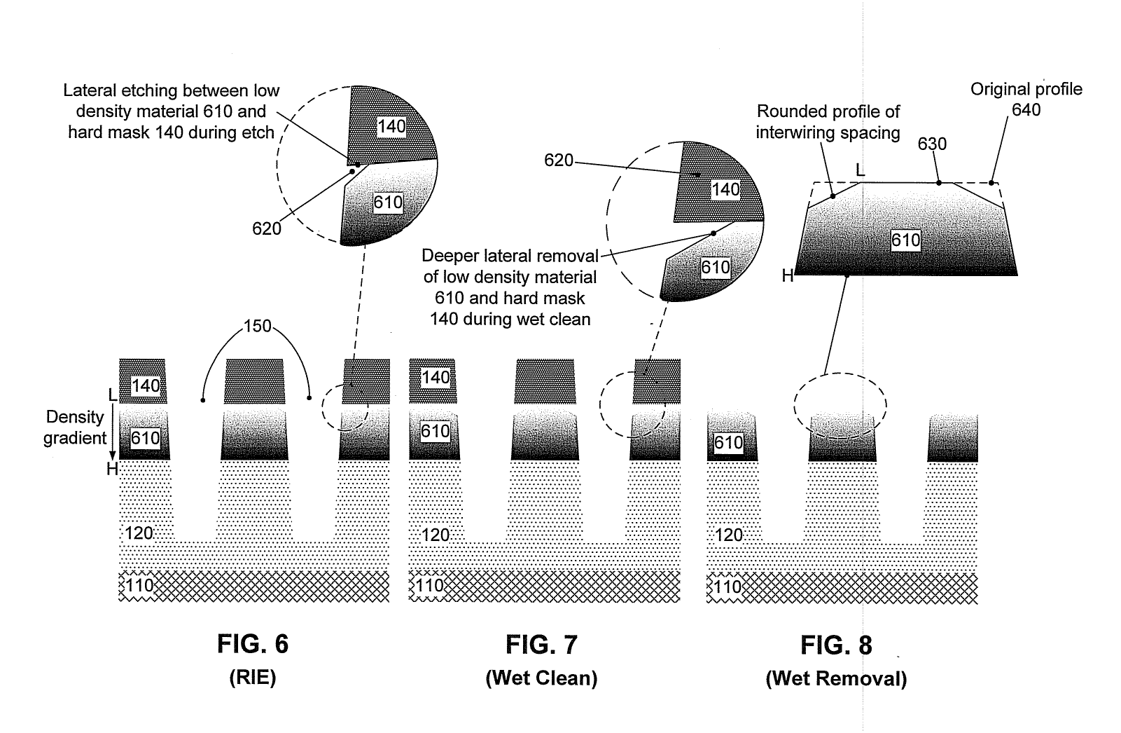

Turning to FIGS. 6-11, illustrated are a series of exemplary, non-limiting embodiments to facilitate filling of a trench(es) having a high aspect ratio (e.g., w2:d2 of FIG. 5). In an aspect, the trench may have a width (w2) of about 30 nm and a depth (d2) of about 150 nm and hence the aspect ratio is 0.2 (w2:d2) or 5 (d2:w2), however it is to be appreciated that the values for w2 and d2 are merely exemplary and the various embodiments presented herein are applicable to any trench aspect ratio.

The layered structure comprises similar layers to that depicted in FIGS. 1-5, e.g., base layer 110, dielectric layer (e.g., low-k material, ultra low-k material) 120 and masking layer 140 (e.g., hard mask TiN). However, rather than the intermediate layer 130 comprising of a material having a constant composition/density throughout, an intermediate layer 610 is formed between layers 120 and 140, where layer 610 comprises a layer having a density gradient of deposited material across the layer. As previously described, layer 130 (reference FIGS. 1-5) can comprise of TEOS, however, such layers are typically formed having a constant structural density throughout. For example, the entire TEOS layer 130 is formed using deposition conditions, e.g., temperature, power, gas flow ratio, pressure, etc., which are continuously maintained to facilitate a constant structural density of deposited material. However, by forming a TEOS layer having a density gradient across the layer it is possible to subsequently etch/clean the layer such that one region of the TEOS layer (e.g., a lower density TEOS region) is preferentially removed with respect to another region of the TEOS layer (e.g., a higher density TEOS region).

As shown in FIG. 6, TEOS layer 610 can be formed having a region of high density material H at the interface of layer 610 with layer 120. The density of TEOS layer 610 is reduced as the layer is formed, with a reduced density L region formed at the interface of layer 610 with layer 140. As mentioned, the high density material at the layer 610/layer 120 interface may be resistant to particular processing conditions (e.g., etching, cleaning, etc.), however the same processing conditions can lead to removal of TEOS from the low density material at the layer 610/layer 140 interface. It is to be appreciated that any suitable range of densities may be utilized to facilitate preferential removal of the low density material in accordance with the various embodiments presented herein. In a non-limiting, exemplary embodiment, the density of TEOS material at the layer 610/layer 140 interface may be about 50% of the density of TEOS at the layer 610/layer 120 interface. However, it is to be appreciated that any ratio of “high density material:low density material” can be utilized to facilitate selective material removal. Formation of a TEOS layer having a density gradient can be produced by controlling the conditions during deposition/formation of the TEOS layer. For example, during the initial stages of layer formation, high power and deposition temperature may be utilized to facilitate formation of the higher density TEOS region, H. During the subsequent deposition, the power and deposition temperatures can be adjusted to a magnitude for producing a lower density region L in the layer. To facilitate formation of a layer with sufficient density gradation, a layer having a thickness greater than is normally used may be formed. For example, a layer of high density-only TEOS of about 15-20 nm thickness may typically used, and to achieve the gradated density a layer may be 25-30 nm thick. However, the thickness is as required to facilitate formation of the gradated structure.

As shown in FIG. 6, during formation of trenches 150 by RIE, the low density TEOS material comprising layer 610 is susceptible to removal and accordingly an undercut 620 is formed owing to the low density TEOS material being removed under the mask layer 140. In effect, owing to the difference in density, TEOS material can be removed laterally from underneath layer 140 in preference to TEOS material being removed in .a vertical manner down the trench 150. Accordingly, TEOS material is removed from region L in preference to region H.

Any suitable RIE process can be utilized with the density gradated TEOS layer 610. As mentioned, in one aspect, the less dense TEOS material can have an etching selectivity, and removal of the low density TEOS occurs due to the ion bombardment of the RIE process. In another aspect, owing to the low density TEOS being located closer to the ion etch apparatus than the high density TEOS (e.g., the low density TEOS is located closer to the opening of the trench), the low density TEOS region can be subjected to greater exposure to the etching gas/ions for a longer period than the high density TEOS region and hence can be removed preferentially.

It is to be appreciated that while the RIE process may be anisotropic in nature and acts in a vertical manner with regard to the semiconductor stack (e.g., in direction d of FIG. 1) owing to the low density TEOS 610, it is possible for some of the low density TEOS 610 to be removed with sufficient ion bombardment.

FIG. 7 illustrates a wet clean operation being performed on the layered structure. After the RIE etching process (as depicted in FIG. 6) a post-etch cleaning process is typically performed. During RIE etch, etching residuals may be formed and are to be removed otherwise subsequent filling of the trench 150 with conductor may be rendered at best problematic, and at worst impossible. The etching residuals can comprise, for example, complex fluoropolymers from an etch gas, metallic or inorganic species from products of the etching process, etc. In an aspect, the residuals may be present as a function of rendering the RIE etch process more directional (e.g., anisotropic).

A suitable cleaner for post RIE etch is hydroflouric acid (HF), although it is to be appreciated that any suitable cleaner can be utilized. In an embodiment, HF cleaner solution can be utilized to remove low density TEOS 610. Any suitable dilution can be utilized in accordance with the various embodiments presented herein, for example, selective removal of low density TEOS in preference to high density TEOS. Accordingly, a HF solution of about 1:100 can be utilized as well as 1:300, 1:1000, etc. Typically a wet clean operation is isotropic in nature and hence, the removal of the low density TEOS 610 during the wet clean process may proceed at a faster rate than for the RIE etch process (see FIG. 6). Accordingly, removal of an initial amount of low density TEOS 610 may occur during RIE etch, and owing to the opening thereformed, the undercut 620 is further enlarged during the post etch wet clean operation. As shown in FIG. 7, the low density TEOS is removed in a preferential manner resulting in the opening to further extend laterally along the layer 610/layer 140 interface. In effect, removal of low density TEOS at the layer 610/layer 140 interface results in layer 610 having a “rounded” profile.

FIG. 8 illustrates removal of layer 140, wherein such removal can occur during a wet clean operation, or post-wet clean operation which results in the peeling of layer 140 from layer 610, for example using a wet solution such as hydrogen peroxide. Owing to the removal of layer 140, surface 630 of the TEOS layer 610 is exposed. As shown in FIG. 8, the surface 630 of the TEOS layer 610 is more rounded compared to the original profile (as indicated by broken line 640). As previously mentioned with regard to FIG. 5, forming interwiring spacings having a rounded profile effectively opens up the trench rendering it easier to subsequently fill the trench with conductor. In an aspect, the peeling of the mask layer 140 improves the aspect ratio of the trench owing to the depth of the trench being reduced by the thickness of the peeled mask layer 140.

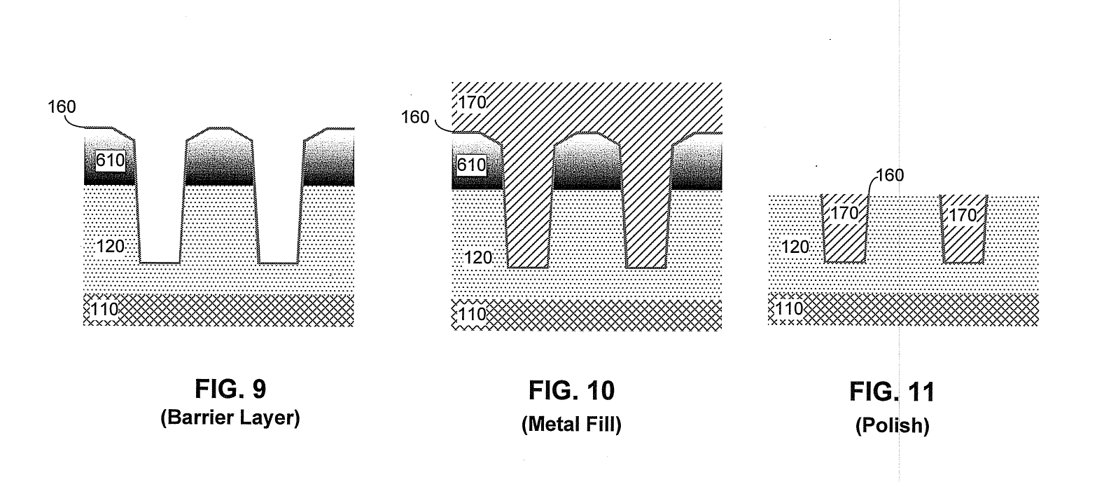

As shown in FIG. 9, the rounded profiles of the TEOS 610 layer enable improved deposition and coverage of barrier layer 160. In an aspect, the rounded profiles of TEOS 610 enable a barrier layer 160 to be deposited which is more continuous in nature with a thickness which can be more consistent throughout compared with a layer which is deposited to mitigate any film thinning effects due to being deposited on a sharp corner (e.g., see FIG. 5, (ii)). And suitable barrier layer material can be utilized, for example, TaN, Ta, TiN, Ti, etc. and can be deposited by any suitable process such as physical vapor deposition (PVD).

As shown in FIG. 10, owing to the rounded profile of the TEOS layers 610 in combination with the reduced aspect ratio resulting from the prior removal of mask layer 140, the metalization operation to form conducting layer 170 is much improved in comparison with a typical process (as shown in FIG. 5). Hence the problem of conductor depositing on the interwiring structures (e.g., FIG. 5, metal buildup 172) has been negated by the selective etching available when using a density-gradient layer 610. As illustrated in FIG. 10, metal 170 can be deposited to fill trenches 150 having a resultant high integrity and in a seamless manner.

FIG. 11 illustrates removal of excess metal 170, TEOS layer 610 and any excess dielectric material in layer 120 along with barrier material 160, as required to form the desired conductive line(s). Any suitable polishing/removal process can be utilized, e.g., chemical mechanical polishing/planarization.

Typically, to fabricate a seamlessly filled metal interconnect in a trench having a high aspect ratio (e.g., the trench is narrow and deep) a plurality of stages may be required during the formation of the trench by the RIE operation, wet cleaning, removal of TiN, shaping of TiN, aspect reduction of the trench, etc., wherein each stage may also have to be repeated. For example, a dry etch can be utilized to generate a rounded profile for layer 140 while a wet solution can be utilized to remove/peel layer 140, however, the combination of generating a rounded profile and layer removal cannot be both achieved in a wet operation. As shown in the various embodiments presented herein, it is possible to create a low aspect ratio trench from a high aspect ratio trench by performing a single process sequence based upon the RIE etch and subsequent removal of etching residuals along with peel of the hard mask layer, where the wet clean and wet removal can be performed as a wet operation.

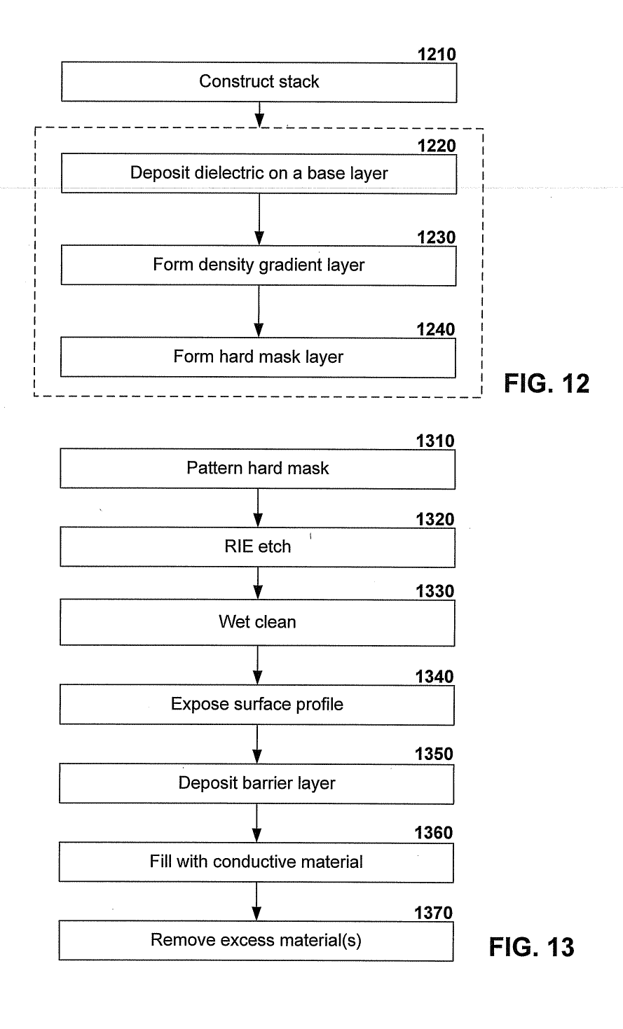

FIG. 12 presents a flow diagram illustrating an exemplary, non-limiting embodiment for formation of a seamlessly filled interconnect structure in a high-aspect ratio trench. At 1210 a semiconductor stack is constructed into which the high-aspect ratio trench is formed. At 1220, a dielectric layer (e.g., dielectric layer 120) is deposited on a base layer (e.g., base layer 110). As described above, the base layer can comprise of a substrate material such as a silicon substrate, a plurality of layers, or a diffusion barrier layer (e.g., a tri-layer cap, etc.) which can comprise of a single layer or a plurality of layers (e.g., SiN, SIC, SiCN, or combination thereof). Subsequently at 1230, a layer (e.g., layer 610) having a density gradation is formed on the dielectric layer. The density gradation material can comprise of any suitable material which exhibits etch selectivity. In an embodiment, the density gradation material can be TEOS. At 1240, a mask layer (e.g., mask layer 140) is deposited onto the density gradation layer. Effectively, the mask layer can comprise of any suitable material to facilitate execution of lithography to facilitate patterning (e.g., trench formation) in the semiconductor stack, for example TIN. In an aspect, selection of the mask layer material may be undertaken in consideration of the etch selectivity of the mask layer material with reference to the etching susceptibility of the density gradation material, thereby facilitating lateral etching/growth of the undercut in the density gradation material while negligible etch of the mask layer occurs.

FIG. 13 presents a flow diagram illustrating an exemplary, non-limiting embodiment to facilitate formation of a seamlessly filled interconnection structure in a high-aspect ratio trench. At 1310 a mask layer (e.g., hard mask layer 410) is patterned to form a desired trench patterning (and subsequently the conductive line patterning).

At 1320, RIE etching of an intermediary density gradated layer (e.g., layer 610) and dielectric layer (e.g., layer 120) is performed to facilitate formation of a trench (e.g., trench(es) 150). In an embodiment, as previously described, the density gradated layer can comprise of TEOS deposited with a variation in density. Owing to the density gradation across the TEOS layer, lower density TEOS can be susceptible to removal in preference to the higher density TEOS. Owing to the density of the TEOS varying from high density TEOS at an interface with the underlying dielectric layer to a lower density TEOS at the interface with the mask layer to form an undercut (e.g., undercut 620). Lower density TEOS is removed from under the mask layer, where in effect removal of the lower density TEOS material can occur in a lateral manner with regard to the overlaying mask layer. The RIE etch operation can be configured such that the RIE etch is anisotropic with regard to the depth of the trench.

At 1330, a post-RIE etch wet clean operation is performed. In comparison with the RIE etch (which can be primarily an anisotropic operation) the wet clean operation can be isotropic in nature and hence result in further extending the degree of low density material removed from under the mask layer. Further, owing to the anisotropic nature, the volume of low density TEOS removed during the wet clean operation can be greater than that removed during the RIE etch. Any suitable etchant can be utilized during the wet clean, for example HF, as required to facilitate removal of the lower density TEOS in relation to the higher density TEOS.

At 1340, the mask layer can be peeled back thereby exposing an upper surface (e.g., surface 630) of the TEOS layer. If no low density TEOS material had been removed then the TEOS layer would have an angular profile. However, owing to the effect of removal of the low density TEOS material from the respective RIE etch and wet clean operations, exposed upper surface of the low density TEOS has a rounded profile (as illustrated in FIG. 8). Any suitable solution can be utilized during the wet removal operation of the mask layer, for example, hydrogen peroxide.

At 1350, a barrier layer (e.g., barrier layer 160) is deposited onto the profiled TEOS layer and dielectric layer to prevent diffusion of metal ions (e.g., Cu or Al) into either of/both of the TEOS layer or the dielectric layer. Deposition of the barrier layer can be by any suitable technique, e.g., PVD.

At 1360, the trench(es) is filled with conductive material (e.g., metallization with Cu, Al, etc.). Owing to the rounded profile of the density gradated TEOS layer in combination with the removal of the mask layer, the ability to fill the trench(es) seamlessly with a high integrity is improved over traditional techniques.

At 1370, any excess deposited conductive material, barrier layer, dielectric, density gradated TEOS, etc., are removed to facilitate final formation of the desired conductive line(s) structure.

Throughout the description, the term dielectric (e.g., dielectric 120) is employed to describe a material having insulating properties being utilized to separate other layers, and can include one or more materials considered to be dielectrics, insulators, etc. In effect, to facilitate description of the various embodiments presented herein the term dielectric is employed to indicate a layer having dielectric or insulative properties compared with the conductive properties of a metal line, metallization layer, etc. Hence, while the term dielectric is employed throughout the description, it is to be appreciated that the term dielectric does not limit a layer to be comprised of dielectric material, rather the layer can comprise of an insulator, or other material acting as a separation layer, wherein separation can either be provided spatially or in terms of a material property, such as provides electrical separation between layers.

Dielectrics can include materials such as an insulative oxide layer, silicon dioxide, silicon oxynitride, boronitride, silicon boronitride and silicon carbide. Dielectric layer(s), as previously mentioned, can also comprise low k inorganic materials and low k polymer materials including polyimides, fluorinated polyimides, polysilsequioxane, benzocyclobutene (BCB), parlene F, parlene N and amorphous polytetrafluoroethylene. A specific example of a commercially available low k polymer material is Flare™ from AlliedSignal believed to be derived from perfluorobiphenyl and aromatic bisphenols. Low k polymer materials provide electrical insulation between various layers, devices and regions within semiconductor substrates.

Further, the semiconductor stack can comprise of an organic film, patterning film, carbon film, or the like, which can be utilized to facilitate formation of a rounded interwiring structure. Where such films can be of any suitable material, e.g., cyclopentene, pyroline, norbornadiene, etc., and of any suitable thickness as to facilitate execution of any embodiments presented herein.

Further, a dielectric, organic film, etc., may be formed to any suitable thickness using any suitable technique, for instance, using chemical vapor deposition (CVD) techniques and physical vapor deposition techniques (PVD). CVD techniques include low pressure chemical vapor deposition (LPCVD) or plasma enhanced chemical vapor deposition (PECVD). In an exemplary, non-limiting embodiment, the mask layer (e.g., mask layer 140) and also the high density portion of the density gradated layer 610 can be employed as an etch stop layer as part of the profiling of the lower density portion of the density gradated layer 610. A particular etch/solution can be utilized to remove a particular layer, or portion thereof (e.g., low density portion of density gradated layer 610), while a different etch/solution is utilized to facilitate removal of another layer (e.g., peeling of mask layer 140). By utilizing different etching/cleaning processes (e.g., different etchants, solutions) desired portions of a particular layer can be removed while portions of the same layer or a disparate layer are left intact. It is to be further appreciated that while only a single layer dielectric, diffusion barrier layer, or substrate (e.g., dielectric 120, base layer 110) is typically shown, the dielectric and/or base layer can comprise of a plurality of layers. For example, a single dielectric can be replaced with a plurality of layers comprising a dielectric layer, interlayer dielectric (ILD), a low k polymer layer, organic film, patterning film, carbon film, a tri-layer cap (e.g., etc.

Any suitable technique can be used to pattern any of the material layers presented herein, (e.g., dielectric 120, gradated density layer 610, mask layer 140, etc.). For example, patterning can be created by employing a photoresist which is patterned using standard photolithographic techniques to form the required pattern to create the pattern, trenches, openings, etc., wherein the photoresist is exposed to electromagnetic radiation through a mask having an image pattern of a desired layout (e.g., desired trenches, openings, line patterning, etc.). Openings are then formed in the photoresist in order to form the desired layout, e.g., by etching away the exposed material (in the case of a positive photoresist) or etching away the unexposed material (in the case of a negative photoresist). Depending on the material of the photoresist, exposure can create a positive or a negative. With a positive photoresist, exposure causes a chemical change in the photoresist such that the portions of the photoresist layer exposed to light become soluble in a developer. With a negative photoresist, the chemical change induced by exposure renders the exposed portions of the photoresist layer insoluble to the developer. After exposure and develop, a layout according to the desired pattern is laid out on the first layer. A subsequent processing step, such as an etching step or an ion implantation step, can be performed and controlled according to the layout. For instance, after exposure and develop, material in the first layer not covered by the photoresist layer can be etched, thus transferring the pattern to the first layer. The photoresist can be subsequently removed. Etching can be by any viable dry or wet etching technique. For example, a wet or dry etching technique can be employed for patterning, while in another aspect, etching can be by a specific anisotropically etch.

As described herein, the formation of a trench can include using anisotropic etching techniques where the etching process can be controlled to occur in a specific direction (unlike standard wet etching) such as vertically down into a stack as the trench is formed between respective layers of dielectric, gradated density layer, and hard mask. An etching technique of particular applicability to the various material processes herein in reactive-ion etching (RIE). In another aspect, plasma ashing can be employed to remove various material layers, etc.

Levelling of layers after formation can be by any suitable technique, e.g., by chemical metal polish (CMP) or other suitable process, in preparation for the next stage in creation of the multilayer stack.

As described, utilization of materials having etch selectivity based on material density combination with patterning of respective masks (e.g., mask layer 140) forms a basis of the various innovative aspects presented herein. In an exemplary, non-limiting embodiment, the hard mask layers can comprise of titanium nitride (TiN), or any other suitable hard mask material such as TaN, silicon dioxide, silicon nitride, silicon oxynitride, boronitride, silicon boronitride, silicon carbide, and the like, and formed by any suitable technique such as CVD, PVD, advanced spin-on methods, etc.

It is to be appreciated that while the formation of an interconnect is described, there may be certain procedures that are not fully disclosed during description of the various embodiments as presented herein. However, rather than provide description of each and every operation involved in the various operations facilitating formation, patterning, removal, etc., of each layer presented herein, for the sake of description only the general operations are described. Hence, while no mention may be presented regarding a particular operation pertaining to aspects of a particular figure, it is to be appreciated that any necessary operation, while either not fully disclosed, or not mentioned, to facilitate formation/deconstruction of a particular layer/element/aspect presented in a particular figure is considered to have been conducted. For example, while no mention may be made regarding a layer described in a preceding figure being leveled (e.g., by chemical metal polish, or other suitable operation) it is considered, for the sake of readability of the various exemplary embodiments presented herein, that the leveling process occurred, as have any other necessary operations. It is appreciated that the various operations, e.g., leveling, chemical metal polish, patterning, photolithography, spin coating, deposition, etching, RIE etch, etc., are well known procedures and are not necessarily expanded upon throughout this description.

The claimed subject matter has been described with reference to the drawings, wherein like reference numerals are used to refer to like elements throughout. In the description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

It is to be appreciated that the various Figures illustrating the various embodiments presented herein are simply rendered to facilitate understanding of the various embodiments. Accordingly, the various embodiments can be applicable to respective elements of any dimension, scaling, area, volume, etc., and while a Figure may illustrate a dimension of one element rendered in association with another element, the respective dimensions, scaling, ratios, etc., are not limited to those as rendered but can be of any applicable magnitude.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim. The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A method for forming an interconnect in a layered semiconductor device, comprising:
forming a dielectric mask layer between a dielectric layer and a hard mask layer, wherein the dielectric mask layer comprising a material density gradient with the density of the dielectric mask layer being higher at an interface of the dielectric mask layer and the dielectric layer, and the density of the dielectric mask layer being lower at an interface of the dielectric mask layer and the hard mask layer.

2. The method of claim 1, further comprising preferentially removing a first portion of the dielectric mask layer with respect to a second portion of the dielectric mask layer, wherein the density of the first portion being lower than the second portion.

3. The method of claim 2, wherein the hard mask layer acting as an etch stop layer controlling removal of the first portion of the dielectric mask layer, wherein the removal occurring laterally along the interface of the hard mask layer and the dielectric mask layer.

4. The method of claim 3, further comprising utilizing wet cleaning for preferentially removing further first portion of dielectric mask layer.

5. The method of claim 4, further comprising removing the hard mask layer exposing a surface of the dielectric mask layer, wherein the surface of the dielectric mask layer being profiled by the removal of the first portion of the dielectric mask layer.

6. The method of claim 2, utilizing reactive ion etching to preferentially remove the first portion of the dielectric mask layer.

7. The method of claim 4, wherein the wet cleaning utilizing hydrofluoric acid solution.

8. The method of claim 1, wherein the dielectric mask layer comprising tetraethyl orthosilicate.

9. The method of claim 1, wherein the hard mask layer comprising titanium nitride.

10. The method of claim 1, forming at least one trench in the layers of dielectric layer, dielectric mask layer, and hard mask layer comprising the layered semiconductor device.

11. The method of claim 1, wherein the forming of the dielectric layer is on a diffusion barrier layer.

12. A multilayer semiconductor stack comprising:
a dielectric layer;
a hard mask layer; and
a dielectric mask layer, wherein the dielectric mask separates the dielectric layer and the hard mask layer, the dielectric mask layer formed with a gradation in density across the dielectric mask layer, the density of the dielectric mask layer being highest at an interface of the dielectric mask layer and the dielectric layer, and the density of the dielectric mask layer being lowest at the interface of the dielectric mask layer and the hard mask layer.

13. The multilayer semiconductor stack of claim 12, wherein the lowest density dielectric mask material is more susceptible to removal than the higher density dielectric mask material.

14. The multilayer semiconductor stack of claim 12, wherein the lowest density dielectric mask material is removed in preference to the higher density dielectric mask material.

15. The multilayer semiconductor stack of claim 12, wherein a first portion of the lower density dielectric mask material is removed during a reactive ion etch process performed to create a trench in the multilayer semiconductor stack.

16. The multilayer semiconductor stack of claim 15, wherein a second portion of the lower density dielectric mask material is removed during a wet clean process performed to create a trench in the multilayer semiconductor stack.

17. The multilayer semiconductor stack of claim 16, wherein at least one of the first portion of the lower density dielectric mask material or the second portion of the lower density dielectric mask material is removed in vicinity to the interface of the dielectric mask layer and the hard mask layer.

18. The multilayer semiconductor stack of claim 12, wherein the dielectric mask layer comprises tetraethyl orthosilicate.

19. A method for forming an interconnect in a layered semiconductor device, comprising:
forming a first layer;
depositing a second layer on the first layer;
depositing a third layer on the second layer; wherein deposition of the second layer is controlled forming a density gradation across the second layer, the density of the second layer is higher at the interface of the second layer and the first layer, and the density of the second layer is lower at the interface of the second layer and the third layer;
removing lower density second layer material preferentially over the higher density second layer material facilitating forming of an undercut at the interface between the second layer and the third layer.

20. The method of claim 19, wherein the second layer comprising tetraethyl orthosilicate.
